(19) United States
(12) Patent Application Publication
(10) Pub. No.: US 2025/0151447 A1
(43) Pub. Date: May 8, 2025

(54) Semiconductor Device and Method of Making a Semiconductor Package with a Glass Cover

(71) Applicant: UTAC Headquarters Pte. Ltd., Singapore (SG)

(72) Inventors: Jeffrey Punzalan, Singapore (SG); Catherine Chang, Singapore (SG); Il Kwon Shim, Singapore (SG)

(73) Assignee: UTAC Headquarters Pte. Ltd., Singapore (SG)

(21) Appl. No.: 18/927,456

(22) Filed: Oct. 25, 2024

Related U.S. Application Data
(60) Provisional application No. 63/595,614, filed on Nov. 2, 2023.

(51) Int. Cl. H01L 27/146

(52) U.S. Cl. CPC H10F 39/811; H10F 39/024; H10F 39/804; H10F 39/8063

(57) ABSTRACT

A semiconductor device has a semiconductor die including a photonic circuit. A first adhesive bead is deposited over the semiconductor die around the photonic circuit. A second adhesive bead is deposited over the first adhesive bead. An inner edge of the second adhesive bead is offset toward the photonic circuit relative to an inner edge of the first adhesive bead. A lens is disposed over the second adhesive bead. An encapsulant is deposited over the semiconductor die and lens.

### CLAIM OF DOMESTIC PRIORITY

The present application claims the benefit of U.S. Provisional Application No. 63/595,614, filed Nov. 2, 2023, which application is incorporated herein by reference.

### FIELD OF THE INVENTION

The present invention relates in general to semiconductor devices and, more particularly, to a semiconductor device and method of making a semiconductor package with a glass cover.

### BACKGROUND OF THE INVENTION

Semiconductor devices are commonly found in modern electronic products. Semiconductor devices perform a wide range of functions, such as signal processing, high-speed calculations, sensors, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Optically sensitive semiconductor devices commonly have a lens or other optically transmissive lid or cover disposed over a photosensitive or photonic circuit on a semiconductor die. Packaging the semiconductor die typically includes attaching the lens, lid, or cover to a photonic semiconductor die using adhesive. The cover protects the photonic circuit and in some cases conditions or focuses light for the photonic circuit. Existing methods of attaching lenses, lids, or covers to photonic semiconductor die are unsatisfactory in several ways. Therefore, a need exists for improved semiconductor devices and methods of making semiconductor devices with glass covers.

### BRIEF DESCRIPTION OF THE DRAWINGS

FIGS. 1a-1c illustrate a semiconductor wafer with a plurality of photonic semiconductor die separated by a saw street;

FIGS. 2a-2e illustrate a process of forming an optical semiconductor package with one of the photonic semiconductor die and a lens, lid, or cover;

FIGS. 3a-3g illustrate a process of forming the optical semiconductor package with multiple stacked beads of adhesive between the lens and semiconductor die;

FIG. 4 illustrates a second stacked adhesive embodiment;

FIG. 5 illustrates a third stacked adhesive embodiment;

FIG. 6 illustrates a fourth stacked adhesive embodiment;

FIG. 7 illustrates an alternative encapsulation embodiment; and

FIG. 8 illustrates one of the semiconductor packages mounted on a substrate of a larger electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

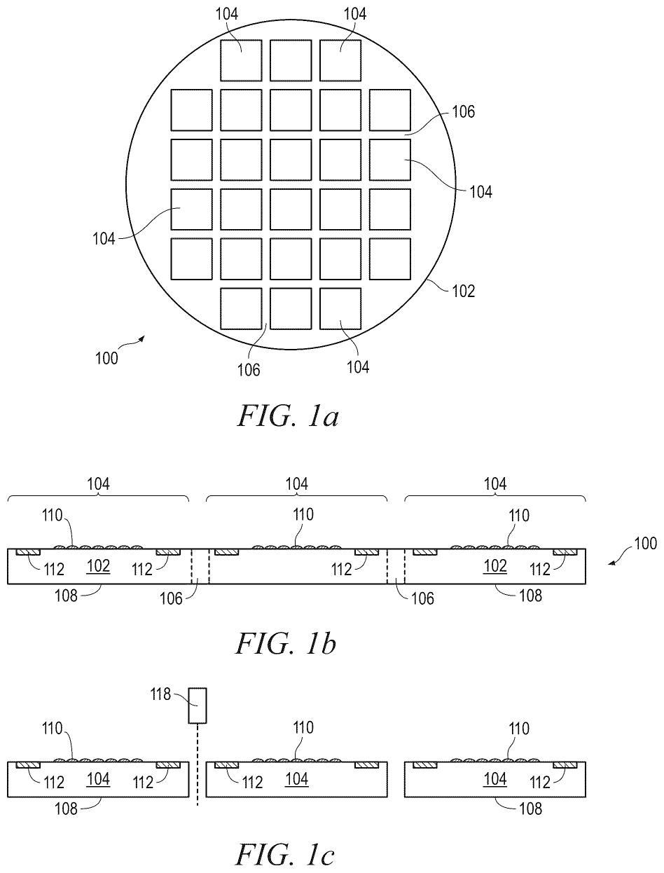

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface including a photosensitive or photonic circuit 110 and additional analog or digital circuits implemented as active devices, passive devices, conductive layers, and dielectric layers formed on or within the die and electrically interconnected according to the electrical design and function of the die. For example, the circuit may include one or more transistors, diodes, sensors, and other circuit elements to implement analog circuits or digital circuits, such as digital signal processor (DSP), application specific integrated circuits (ASIC), memory, or other signal processing circuits. Semiconductor die 104 may also contain integrated passive devices (IPDs), such as inductors, capacitors, and resistors, for RF signal processing. Semiconductor die 104 can implement a digital camera, luminescence sensor, or any other photosensitive device. In one embodiment, photonic circuit 110 is a CMOS image sensor.

An electrically conductive layer 112 is formed over the active surface using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), platinum (Pt), or other suitable electrically conductive material. Conductive layer 112 operates as contact pads electrically connected to the circuits on the active surface, including photonic circuit 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known-good die (KGD) post singulation.

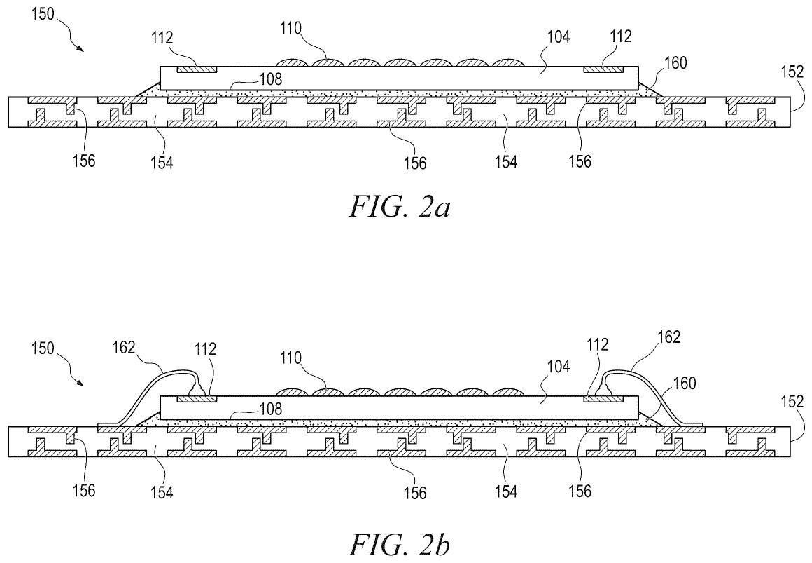

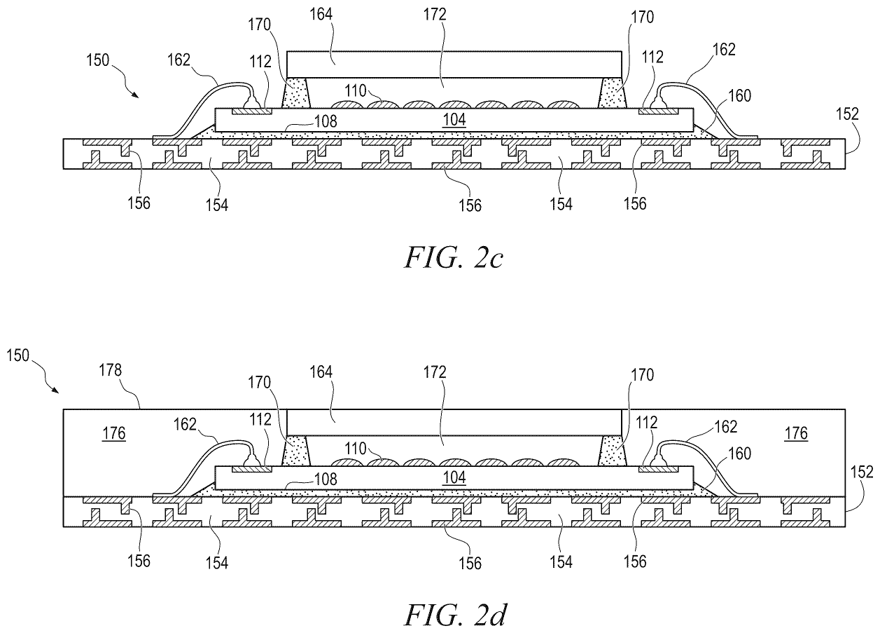

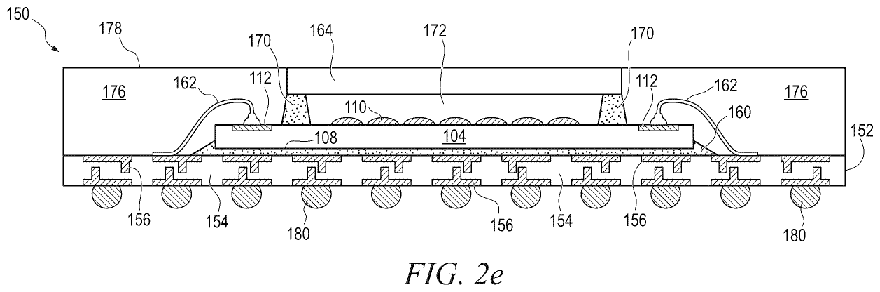

FIGS. 2a-2e illustrate a process of forming a semiconductor package 150 with photonic semiconductor die 104. FIG. 2a shows a partial cross-sectional view of a substrate 152. While only a single substrate 152 is shown, hundreds or thousands of substrates are commonly processed on a common carrier, using the same steps described herein for a single unit but performed en masse. Substrate 152 could also start out as a single large substrate with multiple units being formed thereon, which are singulated from each other during or after the manufacturing process.

Substrate 152 includes one or more insulating layers 154 interleaved with one or more conductive layers 156. Insulating layer 154 is a core insulating board in one embodiment, with conductive layers 156 patterned over the top and bottom surfaces, e.g., a copper-clad laminate substrate. Conductive layers 156 also include conductive vias electrically coupled through insulating layers 154. Substrate 152 can include any number of conductive and insulating layers interleaved over each other. A solder mask or passivation layer can be formed over either side of substrate 152. Any suitable type of substrate or leadframe is used for substrate 152 in other embodiments.

Substrate 152 in FIG. 2a has semiconductor die 104 mounted thereon, as well as any discrete active or passive components, other semiconductor die, or other components desired for the intended functionality of semiconductor package 150. Any type and number of components can be mounted on both the top and bottom surfaces of substrate 152 or embedded within the substrate. Semiconductor die 104 is disposed on substrate 152 using a pick-and-place process, or another suitable process or device, with photonic circuit 110 and contact pads 112 oriented away from the substrate. A mold underfill or other adhesive 160 is disposed on back surface 108 or substrate 152 prior to mounting semiconductor die 104. Adhesive 160 keeps semiconductor die 104 in place during the manufacturing process.

In FIG. 2b, a plurality of bond wires 162 is formed between contact pads 112 of semiconductor die 104 and contact pads of substrate 152. Bond wires 162 are mechanically and electrically coupled to conductive layer 156 of substrate 152 and to contact pads 112 of semiconductor die 104 by thermocompression bonding, ultrasonic bonding, wedge bonding, stitch bonding, ball bonding, or another suitable bonding technique. Bond wires 162 include a conductive material such as Cu, Al, Au, Ag, a metal alloy, or a combination thereof. Bond wires 162 represent one type of interconnect structure that electrically couples semiconductor die 104 to substrate 152. In other embodiments, solder bumps, conductive pillars, or another suitable interconnect structure is used. Semiconductor die 104 is a flip-chip die with photonic circuit 110 formed on the opposite surface from contact pads 112 in one embodiment.

In FIG. 2c, cover, lid, or lens 164 is disposed on semiconductor die 104 over photonic circuit 110. Lens 164 can alternatively be mounted prior to forming bond wires 162. Lens 164 can be singulated from a square or round panel with a tape or washable epoxy protective layer in some embodiment. Lens 164 has light-transmissive properties to allow an optical signal from outside of package 150 to be detected by photonic circuit 110.

Lens 164 is formed from glass, polymer, or another optically transparent or transmissive material. Lens 164 can have any combination of convex, concave, curved, domed, Fresnel, or other shaped surfaces to guide, condition, or focus light as desired. Lens 164 may also be flat as illustrated and operate primarily to physically protect photonic circuit 110 without significantly modifying light transmitted through the lens. Lens 164 can be totally transparent or have a material or coating that filters one or more wavelengths of light.

Lens 164 is mounted to semiconductor die 104 over photonic circuit 110 using an adhesive 170. Adhesive 170 forms a continuous bead completely around the perimeter of lens 164 and photonic circuit 110 to protect a cavity 172 between the lens and semiconductor die 104 when encapsulant is deposited. Adhesive 170 holds lens 164 in place over photonic circuit 110. Adhesive 170 is deposited onto lens 164 or semiconductor die 104 prior to disposing the lens onto the semiconductor die. In one embodiment, adhesive 170 is an ultraviolet (UV) cured adhesive, thereby allowing adhesive 170 to be cured by a UV light shining through lens 164. In another embodiment, adhesive 170 is thermally or otherwise cured.

In FIG. 2d, an encapsulant or molding compound 176 is deposited over substrate 152, semiconductor die 104, and lens 164, covering side surfaces of the lens and semiconductor die. Encapsulant 176 is an electrically insulating material deposited using a paste printing, compressive molding, transfer molding, liquid encapsulant molding, vacuum lamination, spin coating, or other suitable application process. Encapsulant 176 can be polymer composite material, such as an epoxy resin, epoxy acrylate, or polymer with or without a filler. Encapsulant 176 is non-conductive and environmentally protects the semiconductor device from external elements and contaminants.

Encapsulant 176 is deposited using film-assisted molding or another method that blocks encapsulant 176 from flowing over the top of lens 164. A top surface 178 of encapsulant 176 is made coplanar to the top surface of protective layer 164, as illustrated, by the molding process. In other embodiments, encapsulant 176 is deposited over lens 164 and then removed. Adhesive 170 blocks encapsulant 176 from flowing between lens 164 and semiconductor die 104.

In FIG. 2e, solder bumps 180 are optionally disposed over the bottom surface of substrate 152. A conductive bump material is deposited over substrate 152 opposite semiconductor die 104 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads of conductive layer 156 using a suitable attachment or bonding process. The bump material can be reflowed by heating the material above its melting point to form conductive balls or bumps 180.

If a protective layer remains on lens 164, the protective layer is removed using a process appropriate for the type of protective layer used, e.g., peeling, washing, chemically dissolving, etching, or otherwise removing using any suitable process. If a plurality of semiconductor packages 150 remains as a larger panel, then the semiconductor packages are singulated from each other using a saw blade, laser cutting tool, or other suitable means. Semiconductor package 150 in FIG. 2e is complete and ready to be installed into a larger electronic system to provide photonic functionality.

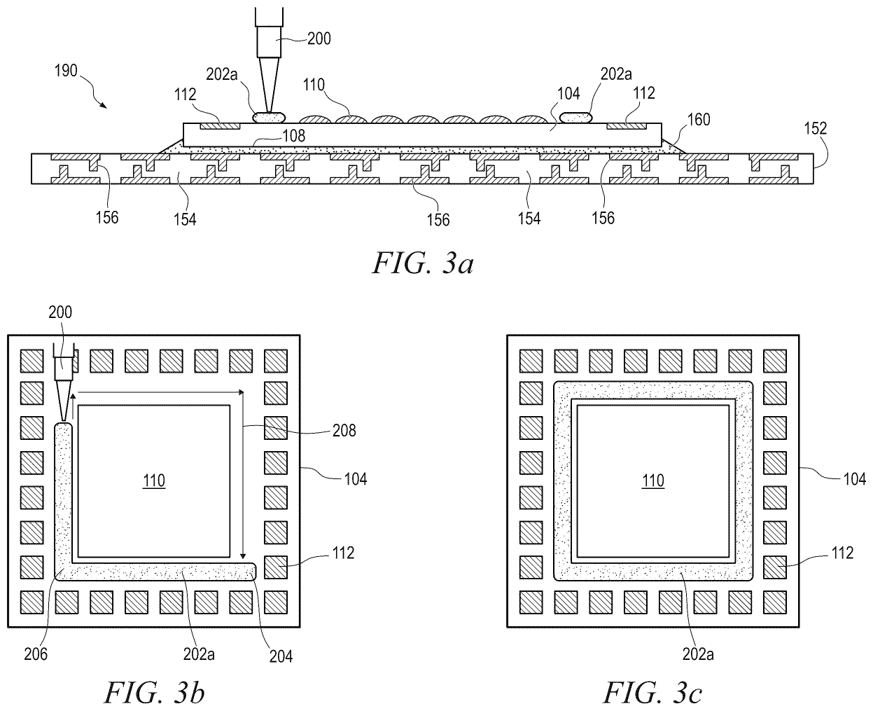

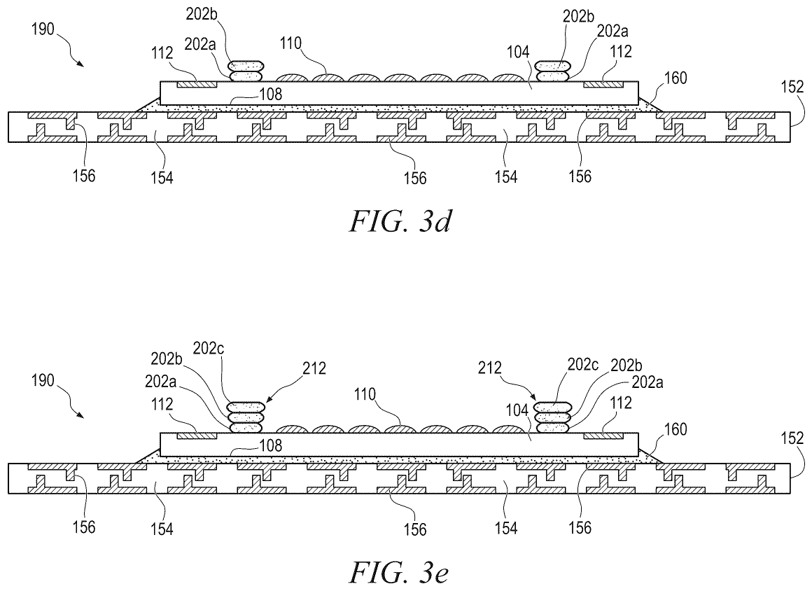

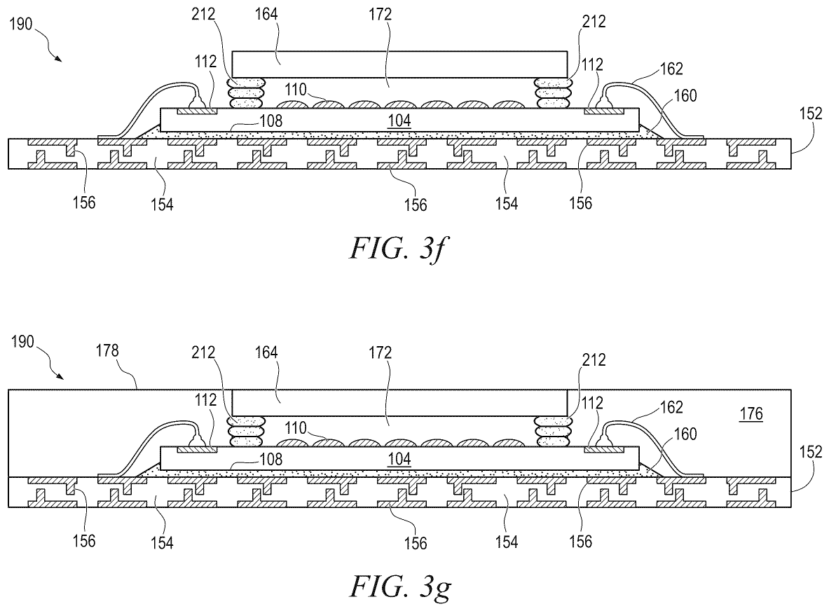

One issue with adhesive 170 is that the large and relatively flat surfaces in cavity 172 tend to reflect light in a way that causes flares on photonic circuit 110. The flares caused by light reflecting off of adhesive 170 can interfere with proper operation of photonic circuit 110. FIGS. 3a-3g illustrate an embodiment where the adhesive between lens 164 and semiconductor die 104 is dispensed as multiple stacked beads of adhesive to alleviate light flares caused by reflections on the adhesive.

FIG. 3a shows a nozzle 200 used to apply a first bead of adhesive 202a. Nozzle 200 is an inkjet printing nozzle in some embodiments. Inkjet printing improves precision of dispensing adhesive and reduces bleed of the adhesive toward photonic circuit 110. The adhesive for bead 202a can be any suitable adhesive, e.g., UV or thermally curable. A pump is attached to nozzle 200 to push adhesive out of the nozzle at a controlled rate. Nozzle 200 is attached to a computer numerical control (CNC) head or other mechanism that allows precise control of the nozzle position in three dimensions, i.e., along the x, y, and z axes. Adhesive bead 202a is dispensed in a continuous path all the way around photonic circuit 110 as with adhesive 170 above.

FIG. 3b shows adhesive bead 202a being dispensed around photonic circuit 110. Application of adhesive begins while head 200 is disposed over point 204. While adhesive is being dispensed, head 200 moves in the X and Y axes around the footprint of photonic circuit 110. The path of travel for head 200 turns 90-degrees at corner 206 to follow the perimeter of photonic circuit 110. The movement of head 200 continues around photonic circuit 110 as indicated by arrows 208 until adhesive bead 202a completely surrounds the photonic circuit as shown in FIG. 3c.

In one embodiment, a vertical thickness of bead 202a is controlled by the height at which the tip of nozzle 200 is placed over the surface of die 104. The thickness of bead 202a can be increased by moving nozzle 200 away from die 104 during dispensing, or reduced by moving the nozzle toward the die. Bead 202a has a flat top surface due to the flat bottom surface of nozzle 200 making a sweeping motion across the entirety of the bead while dispensing the adhesive. A bottom of nozzle 200 is wider than adhesive bead 202a in some embodiments to ensure that the top surface of the bead can be made flat by the nozzle's movement. The adhesive used has a sufficiently high viscosity so that the bead maintains its shape until curing.

A width of bead 202a, in the direction from contact pads 112 and photonic circuit 110, is controlled by a combination of the rate of dispensing adhesive from nozzle 200 and a rate of the movement of the nozzle travelling around photonic circuit 110. Bead 202a can be made wider by dispensing more adhesive per unit time or by moving the nozzle more slowly. Bead 202a can be made narrower by dispensing less adhesive per unit time or by moving the nozzle more quickly.

After dispensing of adhesive bead 202a is complete, a snap or flash cure is applied to partially solidify the adhesive. The snap cure is performed by applying a temperature of between 40-60° C. for 4-6 seconds in some embodiments. Other types of curing are used in other embodiments as appropriate for the specific type of adhesive used, e.g., UV exposure for UV-cured adhesive. At least partially curing adhesive bead 202a allows another bead 202b to be formed on the first bead 202a in FIG. 3d.

Bead 202b is formed using nozzle 200 as described above for bead 202a. Bead 202b is formed in a complete path around photonic circuit 110 as shown in FIGS. 3b and 3c for bead 202a. A thickness of bead 202b is controlled by a height of nozzle 200 over bead 202a during dispensing of adhesive. Bead 202b is made to the same thickness as bead 202a but is different in other embodiments. Bead 202b is made wider compared to bead 202a by reducing the movement speed of nozzle 200 or by increasing the flow rate of adhesive out of the nozzle. Therefore, the edges of bead 202b, both the edges oriented toward and also away from photonic circuit 110, extend out past the corresponding edges of bead 202a and outside a footprint of the underlying adhesive bead. After dispensing, second adhesive bead 202b is snap cured as described for bead 202a.

A third bead 202c is formed on the second bead 202b in FIG. 3e. Bead 202c is formed using nozzle 200 as described above for beads 202a and 202b. Bead 202c is formed in a complete path around photonic circuit 110 as shown in FIGS. 3b and 3c for bead 202a. A thickness of bead 202c is controlled by a height of nozzle 200 over bead 202b during dispensing of adhesive. Bead 202c is made to the same thickness as beads 202a and 202b but is different in other embodiments. Bead 202c is made wider compared to bead 202b by reducing the movement speed of nozzle 200 or by increasing the flow rate of adhesive out of the nozzle. Therefore, the edges of bead 202c, both the edges oriented toward and also away from photonic circuit 110, extend out past the corresponding edges of beads 202a and 202b and outside a footprint of the underlying adhesive beads. After dispensing, third adhesive bead 202c is optionally snap cured as described for bead 202a. Alternatively, cover 164 is mounted onto bead 202c and then the final bead is snap cured.

FIG. 3f shows lens 164 mounted on top of adhesive stack 212. Encapsulant 176 is deposited in FIG. 3g to complete package 190. Adhesive beads 202a-202c can be only partially cured prior to disposing lens 164 on adhesive stack 212, and then fully cured at the same time as encapsulant 176 is cured. Bumps 180 are optionally formed on the bottom of substrate 152. Package 190 is formed as described above for package 150, except that adhesive 170 is replaced by a stack 212 of adhesive beads 202.

The illustrated embodiment uses three adhesive beads 202a-202c to form an adhesive stack 212. Any number of beads can be stacked depending on the desired bead thickness and standoff height for lens 164. Bead thickness may be limited by adhesive viscosity or other factors, which would necessitate more than three beads of adhesive stacked to achieve the same height as stack 212.

Each successive bead 202 in stack 212 is formed wider than the previously formed bead so that the inner surfaces of stack 212 lean in toward photonic circuit 110 as they move up away from die 104. Therefore, the lower adhesive beads 202 are in the shadow of overlying beads for a lot of the angles of light that would otherwise hit lower portions of adhesive 170 in the previous embodiment, resulting in smaller reflections. Beads 202 are able to extend outside of the footprint of underlying beads by having sufficiently high viscosity to stick to the underlying bead and maintain its shape to extend outside of a footprint of the underlying bead. The inner surfaces of each individual bead 202 are rounded, which does a better job diffusing reflected light than the substantially flat surfaces of adhesive 170 above.

Forming adhesive stack 212 by stacking a plurality of adhesive beads 202 reduces the amount of light deflections hitting photonic circuit 110, thus minimizing failures due to light flares. Bead stack 212 has a more stable and a higher bond line thickness (BLT) glue pattern than adhesive 170 due to the individual beads 202 having a more controllable and stable thickness. The first bead 202a can be made significantly thinner compared to adhesive 170 above so the overall adhesive area on die 104 is reduced, thus allowing a larger sensor area.

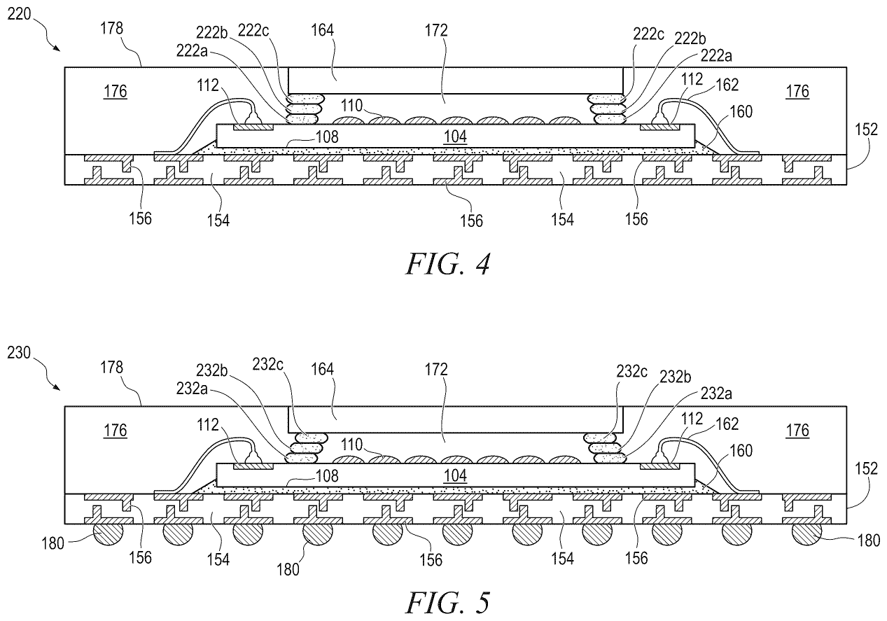

FIG. 4 illustrates another embodiment as photonic semiconductor package 220. Package 220 is formed with a stack of three adhesive beads 222a, 222b, and 222c formed in substantially the same way as described above for beads 202a-202c. Bead 222a is formed directly on die 104, bead 222b is formed on bead 222a, and bead 222c is formed on bead 222b. In package 220, each successive bead is formed with its outer side surface aligned to the underlying bead while its inner side surface, oriented toward photonic circuit 110, extends further in toward the photonic circuit than in package 190. Each bead 222a-222c in FIG. 4 has the same volume of adhesive, i.e., the same height and width, as a corresponding bead 202a-202c in FIG. 3g, but is shifted inward toward photonic circuit 110. The width of adhesive beads can be easily controlled and known in advance, so shifting each bead horizontally the same distance that it would otherwise overhang the outer edge of an underlying bead is easy to accomplish. Moving higher beads of adhesive more inward increases the benefit of blocking light from hitting the lower beads from a wider angle by having the higher beads cast a larger shadow.

FIG. 5 illustrates another embodiment as photonic semiconductor package 230. Package 230 is formed with a stack of three adhesive beads 232a, 232b, and 232c formed in substantially the same way as described above for beads 202a-202c. Bead 232a is formed directly on die 104, bead 232b is formed on bead 232a, and bead 232c is formed on bead 232b. In package 230, each bead 232 is formed with the same volume of adhesive, i.e., width and height, as each other. To provide a stack that leans in toward photonic circuit 110, each successive bead 232 is shifted inward compared to the underlying beads to help block light from reflecting on the lower adhesive beads.

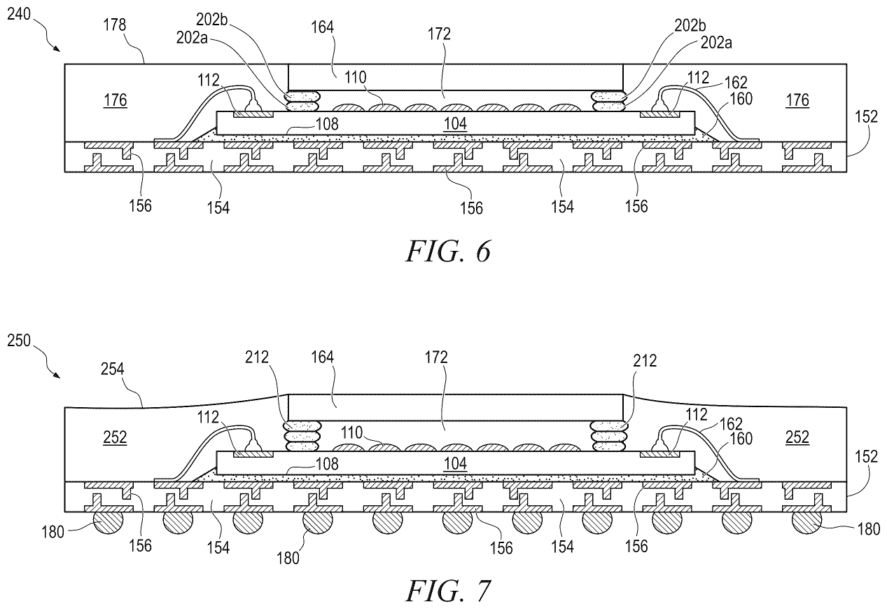

FIG. 6 shows an embodiment as photonic semiconductor package 240. Package 240 is formed with only two stacked adhesive beads 202a and 202b. Bead 202c is not formed. Rather, lens 164 is disposed directly on the second bead 202b. Any of the above or below embodiments can be implemented with two, or more than three, beads stacked using the same general width rules, e.g., all beads having the same width but shifted inward, or each bead having its outer edge aligned while extending inward past the underlying beads.

FIG. 7 shows an alternative encapsulant as package 250 with encapsulant 252. Encapsulant 252 is deposited by fill epoxy being deposited over substrate 152 up to the top of lens 164. Surface tension of fill epoxy 252 before curing causes the epoxy to extend up the sides of lens 164 while sagging toward the edges of package 250. Encapsulant 252, or any other suitable encapsulation method, can be used in any of the above or below embodiments.

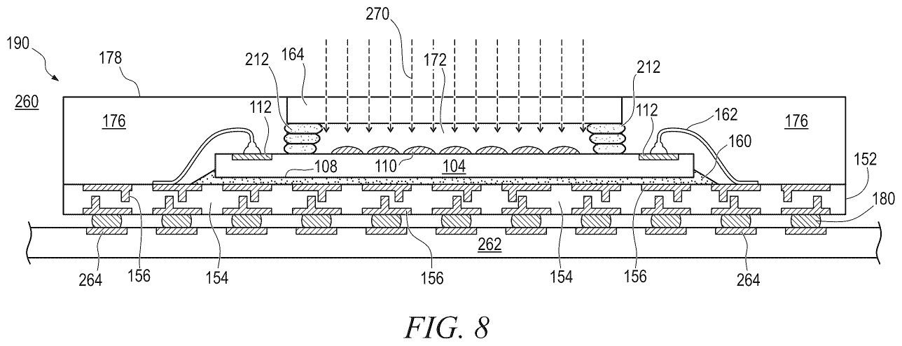

FIG. 8 illustrates integrating the above-described semiconductor packages, e.g., semiconductor package 190, into a larger electronic device 260. FIG. 8 is a partial cross-section of package 190 mounted onto a printed circuit board (PCB) or other substrate 262 as part of electronic device 260.

Bumps 180 are reflowed onto conductive layer 264 of PCB 262 to physically attach and electrically connect semiconductor package 190 to the PCB. In other embodiments, thermocompression or other suitable attachment and connection methods are used. In some embodiments, an adhesive or underfill layer is used between package 190 and PCB 262. Semiconductor die 104 is electrically coupled to conductive layer 264 through substrate 152 to allow use of the functionality of package 190 to the larger system.

Electronic device 260 can have one type of semiconductor package, or multiple types of semiconductor packages, depending on the application. Electronic device 260 can be a stand-alone system that uses the semiconductor packages to perform one or more electrical functions. Alternatively, electronic device 260 can be a subcomponent of a larger system. For example, electronic device 260 can be part of a tablet computer, cellular phone, digital camera, communication system, or other electronic device. Package 190 can operate as, e.g., a camera or luminescence sensor for electronic device 260, converting light rays 270 into a sensor reading or photographic image. Semiconductor packages 190 have a higher reliability due to being formed with multiple beads 202 of adhesive stacked together.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor die including a photonic circuit;
depositing a first adhesive bead over the semiconductor die around the photonic circuit;
depositing a second adhesive bead over the first adhesive bead, wherein an inner edge of the second adhesive bead is offset toward the photonic circuit relative to an inner edge of the first adhesive bead;
disposing a lens over the second adhesive bead; and
depositing an encapsulant over the semiconductor die and lens.

2. The method of claim 1, further including depositing a third adhesive bead over the second adhesive bead, wherein an inner edge of the third adhesive bead is offset toward the photonic circuit relative to the inner edge of the second adhesive bead.

3. The method of claim 1, further including creating the offset of the inner edge of the second adhesive bead by increasing a volume of the second adhesive bead relative to a volume of the first adhesive bead.

4. The method of claim 1, further including creating the offset of the inner edge of the second adhesive bead by changing a position of the second adhesive bead relative to the first adhesive bead while maintaining a volume of the second adhesive bead equal to a volume of the first adhesive bead.

5. The method of claim 1, further including forming the second adhesive bead to include an outer edge, oriented away from the photonic circuit, directly over an outer edge of the first adhesive bead.

6. The method of claim 1, further including snap curing the first adhesive bead prior to depositing the second adhesive bead.

7. The method of claim 1, further including:
disposing the semiconductor die over a substrate;
forming a bond wire connecting the semiconductor die to the substrate;
depositing the encapsulant over the bond wire and substrate; and
forming a solder bump on the substrate opposite the semiconductor die.

8. A method of making a semiconductor device, comprising:
providing a semiconductor die;
depositing a first adhesive bead over the semiconductor die;
depositing a second adhesive bead over the first adhesive bead, wherein an edge of the second adhesive bead is offset relative to a corresponding edge of the first adhesive bead; and
disposing a lens over the second adhesive bead.

9. The method of claim 8, further including depositing a third adhesive bead over the second adhesive bead, wherein an edge of the third adhesive bead is offset relative to the edge of the second adhesive bead.

10. The method of claim 8, further including creating the offset of the edge of the second adhesive bead by increasing a volume of the second adhesive bead relative to a volume of the first adhesive bead.

11. The method of claim 8, further including creating the offset of the edge of the second adhesive bead by changing a position of the second adhesive bead relative to the first adhesive bead while maintaining a volume of the second adhesive bead equal to a volume of the first adhesive bead.

12. The method of claim 8, further including forming the second adhesive bead to include a second edge directly over a second edge of the first adhesive bead.

13. The method of claim 8, further including snap curing the first adhesive bead prior to depositing the second adhesive bead.

14. The method of claim 8, further including:
disposing the semiconductor die over a substrate;
forming a bond wire connecting the semiconductor die to the substrate;
depositing the encapsulant over the bond wire and substrate; and
forming a solder bump on the substrate opposite the semiconductor die.

15. A semiconductor device, comprising:
a semiconductor die;
a first adhesive bead deposited over the semiconductor die;
a second adhesive bead deposited over the first adhesive bead, wherein an edge of the second adhesive bead is offset relative to a corresponding edge of the first adhesive bead; and
a lens disposed over the second adhesive bead.

16. The semiconductor device of claim 15, further including a third adhesive bead deposited over the second adhesive bead, wherein an edge of the third adhesive bead is offset relative to the edge of the second adhesive bead.

17. The semiconductor device of claim 15, wherein a volume of the second adhesive bead is greater than a volume of the first adhesive bead.

18. The semiconductor device of claim 15, wherein a position of the second adhesive bead is shifted relative to the first adhesive bead, and wherein a volume of the second adhesive bead is equal to a volume of the first adhesive bead.

19. The semiconductor device of claim 15, wherein the second adhesive bead includes a second edge directly over a second edge of the first adhesive bead.

20. The semiconductor device of claim 15, further including:
a substrate with the semiconductor die disposed over the substrate; and
a bond wire connecting the semiconductor die to the substrate.
